(19) United States
(12) Patent Application Publication
(10) Pub. No.: US 2024/0014315 A1
(43) Pub. Date: Jan. 11, 2024

(54) SEMICONDUCTOR DEVICE INCLUDING GRAPHENE

(71) Applicant: Samsung Electronics Co., Ltd., Suwon-si (KR)

(72) Inventors: Keunwook Shin, Suwon-si (KR); Changhyun Kim, Suwon-si (KR); Kyung-Eun Byun, Suwon-si (KR); Eunkyu Lee, Suwon-si (KR)

(73) Assignee: Samsung Electronics Co., Ltd., Suwon-si (KR)

(21) Appl. No.: 18/157,416

(22) Filed: Jan. 20, 2023

(30) Foreign Application Priority Data
Jul. 7, 2022 (KR) 10-2022-0083913

(51) Int. Cl. H01L 29/78; H01L 29/423; H01L 29/16; H01L 29/417

(52) U.S. Cl. CPC H01L 29/7813; H01L 29/4236; H01L 29/1606; H01L 29/41741

(57) ABSTRACT

A semiconductor device may include a substrate including a source region and a drain region in a trench, a gate insulating layer in the trench, and a gate electrode in the trench. The gate electrode may include a lower filling portion and an upper filling portion surrounded by the gate insulating layer. The lower filling portion may include a first conductive layer surrounded by the gate insulating layer and may fill a lower region of the trench. The upper filling portion may include a second conductive layer surrounded by the gate insulating layer and may fill an upper region of the trench. The first conductive layer may include graphene doped with metal.

### CROSS-REFERENCE TO RELATED APPLICATION

This application is based on and claims priority under 35 U.S.C. § 119 to Korean Patent Application No. 10-2022-0083913, filed on Jul. 7, 2022 in the Korean Intellectual Property Office, the disclosure of which is incorporated by reference herein in its entirety.

### BACKGROUND

### 1. Field

The disclosure relates to a semiconductor device including graphene.

### 2. Description of the Related Art

A transistor is a semiconductor device that performs the function of electric switching, and is used in various integrated circuit devices including a memory, a driving integrated circuit (IC), a logic device, etc. To increase the degree of integration of an IC device, research has been conducted to develop a transistor having a reduced size while maintaining performance.

Recently, research on a buried channel array transistor (BCAT) structure, which occupies less area and is capable of securing a sufficient effective distance of a channel, has been conducted. The BCAT structure includes a structure in which a trench formed between a source region and a drain region of a substrate is filled with a gate electrode. In this case, a specific resistance of the gate electrode increases due to size reduction of the transistor, such that electrical characteristics required by products may not be obtained.

### SUMMARY

Provided is a semiconductor device having excellent electrical characteristics by controlling a work function.

Additional aspects will be set forth in part in the description which follows and, in part, will be apparent from the description, or may be learned by practice of the presented embodiments of the disclosure.

According to an embodiment, a semiconductor device may include a substrate including a trench, a source region, and a drain region, the source region and the drain region spaced apart from each other by the trench; a gate insulating layer covering a bottom surface of the trench and an inner surface of the trench; and a gate electrode in the trench. The gate electrode may include a lower filling portion and an upper filling portion surrounded by the gate insulating layer. The lower filling portion may be in the trench and may fill a lower region of the trench. The upper filling portion may be on the lower filling portion and may fill an upper region of the trench. The lower filling portion may include a first conductive layer surrounded by the gate insulating layer and filling the lower region of the trench. The upper filling portion may include a second conductive layer surrounded by the gate insulating layer and may fill the upper region of the trench. The first conductive layer may include graphene doped with metal.

In some embodiments, the graphene doped with metal may include at least one of ruthenium (Ru), aluminum (Al), titanium (Ti), platinum (Pt), tantalum (Ta), rhodium (Rh), iridium (Ir), cobalt (Co), and tungsten (W).

In some embodiments, in the graphene doped with metal, a ratio of metal to carbon may be 0.2 at % to 50 at %.

In some embodiments, in the graphene doped with metal, a ratio of carbon having an sp² bond structure to total carbon may be 50% to 99%.

In some embodiments, the graphene doped with metal may include intrinsic graphene or nanocrystalline graphene.

In some embodiments, the graphene doped with metal may include the nanocrystalline graphene and the nanocrystalline graphene may include crystals each having a size of 0.5 nm to 100 nm.

In some embodiments, the second conductive layer may include at least one of polysilicon, Al, copper (Cu), Ru, Rh, Ir, molybdenum (Mo), W, palladium (Pd), Pt, Co, Ta, Ti, nickel (Ni), titanium nitride (TiN), and tantalum nitride (TaN).

In some embodiments, the second conductive layer may include the polysilicon doped with an N-type dopant or polysilicon doped with a P-type dopant.

In some embodiments, the semiconductor device may further include a capping layer on the gate electrode.

In some embodiments, the lower filling portion may further include a barrier layer covering a bottom surface of the gate insulating layer and a lower region of an inner surface of the gate insulating layer, and the barrier layer may surround the first conductive layer in the trench.

In some embodiments, the upper filling portion may further include a two-dimensional material layer in contact with an upper region of the inner surface of the gate insulating layer, and the two-dimensional material layer may surround the second conductive layer.

In some embodiments, the two-dimensional material layer may include at least one of black phosphorus, amorphous boron nitride, two-dimensional hexagonal boron nitride (h-BN), phosphorene, a transition metal dichalcogenide, titanium oxide (TiOₓ), niobium oxide (NbOₓ), manganese oxide (MnOₓ), vanadium oxide (VOₓ), manganese trioxide (MnO₃), tantalum trioxide (TaO₃), tungsten trioxide (WO₃), molybdenum dichloride (MoCl₂), chromium trichloride (CrCl₃), ruthenium trichloride (RuCl₃), bismuth triiodide (BiI₃), lead tetrachloride (PbCl₄), germanium sulfide (GeS), gallium sulfide (GaS), germanium selenide (GeSe), gallium selenide (GaSe), platinum diselenide (PtSe₂), diindium triselenide (In₂Se₃), gallium telluride (GaTe), indium sulfide (InS), indium selenide (InSe), and indium telluride (InTe).

In some embodiments, the transition metal dichalcogenide may include a metal element and a chalcogen element. The metal element may include one of Mo, W, niobium (Nb), vanadium (V), Ta, Ti, zirconium (Zr), hafnium (Hf), technetium (Tc), rhenium (Re), Cu, gallium (Ga), indium (In), tin (Sn), germanium (Ge), and lead (Pb). The chalcogen element may include one of sulfur (S), selenium (Se), and tellurium (Te).

In some embodiments, the two-dimensional material layer may cover an upper surface of the first conductive layer.

In some embodiments, the two-dimensional material layer may have a thickness of 0.3 nm to 5 nm.

According to an embodiment, a semiconductor device may include a substrate including a trench, a source region, and a drain region, the source region and the drain region being spaced apart from each other by the trench; a gate insulating layer covering a bottom surface of the trench and an inner surface of the trench; and a gate electrode in the trench. The gate electrode may include a two-dimensional material layer and a conductive layer. The two-dimensional material layer may cover an upper region of a sidewall of the gate insulating layer in the trench. The conductive layer may fill the trench and may be surrounded by the gate insulating layer and the two-dimensional material layer. The conductive layer may include graphene doped with metal.

In some embodiments, the graphene doped with metal may include at least one of ruthenium (Ru), aluminum (Al), titanium (Ti), platinum (Pt), tantalum (Ta), rhodium (Rh), iridium (Ir), cobalt (Co), and tungsten (W).

In some embodiments, in the graphene doped with metal, a ratio of metal to carbon may be 0.2 at % to 50 at %.

In some embodiments, in the graphene doped with metal, a ratio of carbon having an sp² bond structure to total carbon may be 50% to 99%.

In some embodiments, the graphene doped with metal may include intrinsic graphene or nanocrystalline graphene.

In some embodiments, the graphene doped with metal may include the nanocrystalline graphene and the nanocrystalline graphene may include crystals each having a size of 0.5 nm to 100 nm.

In some embodiments, the semiconductor device may further include a capping layer on the gate electrode.

In some embodiments, the gate electrode may further include a barrier layer covering a bottom surface of the gate insulating layer and a lower region of an inner surface of the gate insulating layer in the trench.

In some embodiments, the two-dimensional material layer may include at least one of black phosphorus, amorphous boron nitride, two-dimensional hexagonal boron nitride (h-BN), phosphorene, transition metal dichalcogenide, titanium oxide (TiOₓ), niobium oxide (NbOₓ), manganese oxide (MnOₓ), vanadium oxide (VOₓ), manganese trioxide (MnO₃), tantalum trioxide (TaO₃), tungsten trioxide (WO₃), molybdenum dichloride (MoCl₂), chromium trichloride (CrCl₃), ruthenium trichloride (RuCl₃), bismuth triiodide (BiI₃), lead tetrachloride (PbCl₄), germanium sulfide (GeS), gallium sulfide (GaS), germanium selenide (GeSe), gallium selenide (GaSe), platinum diselenide (PtSe₂), diindium triselenide(In₂Se₃), gallium telluride (GaTe), indium sulfide (InS), indium selenide (InSe), and indium telluride (InTe).

In some embodiments, the transition metal dichalcogenide may include a metal element and a chalcogen element. The metal element may include one of Mo, W, niobium (Nb), vanadium (V), Ta, Ti, zirconium (Zr), hafnium (Hf), technetium (Tc), rhenium (Re), copper (Cu), gallium (Ga), indium (In), tin (Sn), germanium (Ge), and lead (Pb). The chalcogen element may include one of sulfur (S), selenium (Se), and tellurium (Te).

According to an embodiment, a memory device may include a semiconductor device; and a capacitor electrically connected to the semiconductor device. The semiconductor device may include a substrate including a trench, a source region, and a drain region, a gate insulating layer covering a bottom surface of the trench and an inner surface of the trench, and a gate electrode in the trench. The source region and the drain region may be spaced apart from each other by the trench. The gate electrode may include a lower filling portion and an upper filling portion surrounded by the gate insulating layer. The lower filling portion may be in the trench and may fill a lower region of the trench. The upper filling portion may be on the lower filling portion and fills an upper region of the trench. The lower filling portion may include a first conductive layer surrounded by the gate insulating layer and fills the lower region of the trench. The upper filling portion may include a second conductive layer surrounded by the gate insulating layer and may fill the upper region of the trench. The first conductive layer may include graphene doped with metal.

According to an embodiment, a semiconductor device may include a substrate including a trench, a source region in the trench, and a drain region in the trench and spaced apart from the source region; a gate insulating layer in the trench between the source region and the drain region, the gate insulating layer covering a bottom surface of the trench and an inner surface of the trench; and a gate electrode in the trench and surrounded by the gate insulating layer. The gate electrode may include a lower filling portion and an upper filling portion. The lower filling portion may be in a lower region of the trench. The lower filling portion may be surrounded by a portion of the substrate below the source region and the drain region. The upper filling portion may be on the lower filling portion and between the source region and the drain region. The lower filling portion may include a first conductive layer. The upper filling portion may include a second conductive layer. The first conductive layer may include graphene doped with metal.

In some embodiments, the graphene doped with metal may include at least one of ruthenium (Ru), aluminum (Al), titanium (Ti), platinum (Pt), tantalum (Ta), rhodium (Rh), iridium (Ir), cobalt (Co), and tungsten (W).

In some embodiments, the graphene doped with metal may include intrinsic graphene or nanocrystalline graphene.

In some embodiments, the semiconductor device may further include a capping layer in the trench on the gate electrode.

In some embodiments, the capping layer may be between the source region and the drain region.

In some embodiments, the second conductive layer may include at least one of polysilicon, Al, copper (Cu), Ru, Rh, Ir, molybdenum (Mo), W, palladium (Pd), Pt, Co, Ta, Ti, nickel (Ni), titanium nitride (TiN), and tantalum nitride (TaN).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a cross-sectional view of a semiconductor device according to an embodiment;

FIG. 1B is a cross-sectional view of a semiconductor device taken along a line A-A′ of FIG. 1A;

FIG. 2 is a graph in which a work function of graphene constituting a semiconductor device is measured, according to an embodiment;

FIG. 3 is a cross-sectional view of a semiconductor device according to another embodiment;

FIG. 4 is a cross-sectional view of a semiconductor device according to another embodiment;

FIG. 5 is a cross-sectional view of a semiconductor device according to another embodiment;

FIG. 6 is a cross-sectional view of a semiconductor device according to another embodiment;

FIG. 7 is a cross-sectional view of a semiconductor device according to another embodiment;

FIG. 8 is a cross-sectional view of a semiconductor device according to another embodiment;

FIG. 9 is a cross-sectional view of a semiconductor device according to another embodiment;

FIG. 10 is a diagram illustrating a configuration of a semiconductor device array according to an embodiment;

FIG. 11 is a cross-sectional view of a memory device according to an embodiment;

FIG. 12 is a conceptual diagram schematically illustrating a device architecture that can be applied to an electronic apparatus according to an example embodiment.

FIG. 13 is a block diagram of an electronic apparatus according to an embodiment; and

FIG. 14 is a schematic block diagram of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

An expression such as “above” or “on” may include not only the meaning of “immediately on in a contact manner”, but also the meaning of “on in a non-contact manner”. Singular forms include plural forms unless apparently indicated otherwise contextually. When a portion is referred to as “comprising” or “including” a component, the portion may not exclude another component but may further include another component unless stated otherwise.

The use of the terms of “the above-described” and similar indicative terms may correspond to both the singular forms and the plural forms. Steps or operations constituting the method may be performed in an appropriate order, and are not necessarily limited to the order described herein, unless the order is explicitly stated or contrary to the description.

Connections or connection members of lines between the components shown in the drawings illustrate functional connections and/or physical or circuit connections by example, and in an actual device, may be illustrated as various alternative or additional functional connections, physical connections, or circuit connections.

The use of all examples or illustrative terms is merely for describing the technical idea of the disclosure in detail, and the scope of the disclosure is not limited by these examples or illustrative terms unless limited by the claims.

Hereinafter, a semiconductor device including graphene is described in detail with reference to the accompanying drawings. In the drawings, like reference numerals denote like components, and sizes of components in the drawings may be exaggerated for convenience of explanation. Also, embodiments to be described below are merely examples, and various modifications may be made from such embodiments.

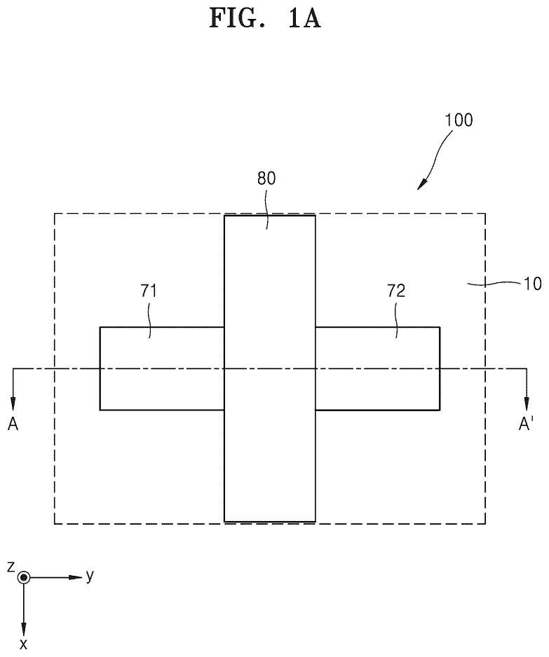

FIG. 1A is a cross-sectional view of a semiconductor device according to an embodiment, and FIG. 1B is a cross-sectional view of the semiconductor device taken along a line A-A′ of FIG. 1A.

Referring to FIGS. 1A and 1B, a semiconductor device 100 may include a substrate 10 including a trench T1, a source region 71 and a drain region 72, arranged to be spaced apart from each other by the trench T1, on the substrate 10, a gate insulating layer 50 covering a bottom surface and an inner surface of the trench T1, a gate electrode 40 including a lower filling portion 41 and an upper filling portion 42, the lower filling portion 41 being arranged in the trench T1 to be surrounded by the gate insulating layer 50 and filling a lower region of the trench T1, and the upper filling portion 42 being arranged on the lower filling portion 41 to be surrounded by the gate insulating layer 50 and filling an upper region of the trench T1, and a capping layer 60 arranged on the gate electrode 40.

The substrate 10 may include a semiconductor substrate. The substrate 10 may include silicon, monocrystal silicon, polysilicon, amorphous silicon, silicon germanium, monocrystal silicon germanium, polycrystal silicon germanium, carbon-doped silicon, or a combination thereof. The substrate 10 may include a Ill/V group semiconductor substrate, e.g., a compound semiconductor substrate, such as a gallium arsenic (GaAs) substrate.

The trench T1 formed by etching a part of the substrate 10 in the vertical direction (z direction) may be arranged in the substrate 10. The source region 71 and the drain region 72 spaced apart from each other in the horizontal direction (y-direction) by the trench T1 may be arranged in the substrate 10. The source region 71 and the drain region 72 may be arranged side-by-side facing the upper region of the trench T1 in the horizontal direction (x- and y-directions). For example, an upper surface of the source region 71 and the drain region 72 and an upper surface of the substrate 10 may be arranged on the same plane. A lower surface of the source region 71 and the drain region 72 may be arranged higher than the bottom surface of the trench T1. The source region 71 and the drain region 72 may be in contact with the inner surface of the trench T1.

The source region 71 and the drain region 72 may be formed by doping a part of the substrate 10 with impurities. The source region 71 and the drain region 72 may also be doped with an N-type or P-type dopant. For example, the source region 71 and the drain region 72 may be formed by doping a part of the substrate 10 with any one of phosphorus (P), arsenic (As), antimony (Sb), and boron (B).

A gate structure 80 may be embedded in the trench T1. The gate structure 80 may include the gate electrode 40, the gate insulating layer 50, and the capping layer 60. The gate electrode 40 may partially fill the inside of the trench T1. The gate insulating layer 50 may be in contact with the bottom surface and the inner surface of the trench T1. The gate electrode 40 may partially fill the inside of the trench T1, and the gate insulating layer 50 may be arranged between the substrate 10 and the gate electrode 40 to surround the gate electrode 40. Accordingly, the gate electrode 40 may not be in direct contact with the bottom surface and the inner surface of the trench T1. The capping layer 60 may be arranged on the gate electrode 40.

The gate electrode 40 may include the lower filling portion 41 and the upper filling portion 42. The lower filling portion 41 may include a first conductive layer 31. The first conductive layer 31 may fill a lower region of the trench T1 and be arranged in the trench T1 to be in contact with a bottom surface of the gate insulating layer 50 and a lower region of an inner surface of the gate insulating layer 50. In addition, because the lower filling portion 41 is provided in the lower region of the inside of the trench T1, the lower filling portion 41 may not overlap the source region 71 and the drain region 72, which are arranged parallel with the upper region of the trench T1, in the horizontal direction (x- and y-directions).

The first conductive layer 31 may include metal-doped graphene. A metal used for doping graphene may include at least one of ruthenium (Ru), aluminum (Al), titanium (Ti), platinum (Pt), tantalum (Ta), rhodium (Rh), iridium (Ir), cobalt (Co), and tungsten (W). A work function of graphene constituting the first conductive layer 31 may be controlled through metal doping. The gate electrode 40 may have a lower resistance as the graphene is doped with metal. In this case, the graphene may include intrinsic graphene or nanocrystalline graphene.

The intrinsic graphene is crystalline graphene and may include crystals having a size greater than about 100 nm. Also, the nanocrystalline graphene may include crystals having a size less than that of the intrinsic graphene. For example, the nanocrystalline graphene may include crystals each having a size of about 0.5 nm to about 100 nm. In the intrinsic graphene, a ratio of carbon having an sp² bond structure to total carbon measured through X-ray photoelectron spectroscopy (XPS) analysis may be nearly 100%. The intrinsic graphene may include little or no hydrogen. A density of the intrinsic graphene may be, e.g., about 2.1 g/cc. In the nanocrystalline graphene, a ratio of carbon having an sp² bond structure to the total carbon may be, e.g., about 50% to about 99%. Also, the nanocrystalline graphene may include hydrogen of, e.g., about 1 atomic percent (at %) to about 20 at %. In addition, a density of the nanocrystalline graphene may be, e.g., about 1.6 g/cc to about 2.1 g/cc.

The graphene may be formed using, e.g., chemical vapor deposition (CVD), plasma enhanced CVD (PECVD), or the like. After the graphene is formed using the CVD or the PECVD, a metal may be deposited on the graphene using, e.g., atomic layer deposition (ALD) or the CVD. Thereafter, when a heat treatment process is performed, carbon atoms in graphene may move between metal particles due to high carbon solid solubility of the metal, and accordingly, metal-doped graphene in which metal particles are dispersed in the graphene may be formed. When necessary, metal-doped graphene may be formed by repeating the process of forming the graphene using the CVD or the PECVD and the process of depositing the metal using the ALD or the CVD a plurality of times.

The upper filling portion 42 may include a second conductive layer 32. The second conductive layer 32 may fill the upper region of the trench T1 and be in contact with the first conductive layer 31. The second conductive layer 32 may include at least one of polysilicon, Al, Cu, Ru, Rh, Ir, molybdenum (Mo), W, palladium (Pd), Pt, Co, Ta, Ti, nickel (Ni), titanium nitride (TiN), and tantalum nitride (TaN). The polysilicon constituting the second conductive layer 32 may be doped with an N-type or P-type dopant. A doping concentration of the polysilicon constituting the second conductive layer 32 may be a relatively high concentration of about 10¹⁹ cm⁻³ or more to reduce a depletion width.

The gate insulating layer 50 may include silicon oxide, silicon nitride, silicon oxynitride, a high-k material, or a combination thereof. The high-k material may include a material having a dielectric constant greater than that of silicon oxide. For example, the high-k material may include a material having a dielectric constant greater than 3.9. The high-k material may include at least one metallic element. The high-k material may include a hafnium-containing material. The hafnium-containing material may include hafnium oxide, hafnium silicon oxide, hafnium silicon oxynitride, or a combination thereof. The high-k material may include lanthanum oxide, lanthanum aluminum oxide, zirconium oxide, zirconium silicon oxide, zirconium silicon oxynitride, aluminum oxide, or a combination thereof. Other known high-k materials may be used as the high-k material.

The capping layer 60 may include an insulating material. For example, the capping layer 60 may include silicon nitride, silicon oxynitride, or a combination thereof. Moreover, the capping layer 60 may include a combination of silicon nitride and silicon oxide.

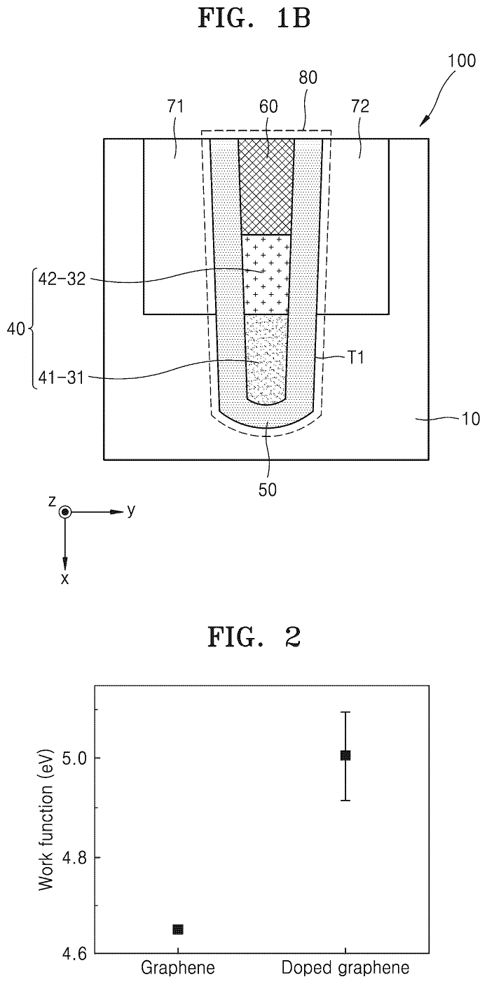

FIG. 2 is a graph in which a work function of graphene constituting a semiconductor device is measured, according to an embodiment.

The graphene constituting the first conductive layer 31 of FIG. 1B may be doped with metal to improve electrical characteristics of the semiconductor device. In other words, graphene may have a doped structure by substituting other elements for some of the elements constituting graphene or by additionally combining other elements. The metal used for doping graphene may include, e.g., at least one of Ru, Al, Ti, Pt, Ta, Rh, Ir, Co, and W, but is not limited thereto.

The metal used for doping graphene may be doped in an amount of, e.g., about 0.2 at % to about 50 at %, with respect to a total amount of graphene. Unlike previously known metallic materials, in metal-doped graphene, charge scattering occurs very rarely even at a thickness of several nm, and thus, at a thickness of several nm, the metal-doped graphene may have a lower resistance than metallic materials of the related art. Therefore, by using metal-doped graphene for a gate electrode, an increase in resistance due to a decrease in thickness of the gate electrode may be suppressed or alleviated.

A work function of graphene may be controlled through metal doping. Undoped graphene may have a work function of about 4.65 eV. When a metal is doped into graphene, doped graphene may have a higher work function than undoped graphene. For example, a work function of metal-doped graphene may be about 4.8 eV to about 5.3 eV. Alternatively, the work function of the metal-doped graphene may be about 4.9 eV to about 5.1 eV. The metal-doped graphene may have a high work function, and may reduce a leakage current and increase a threshold voltage of a semiconductor device.

By forming the gate electrode 40, in particular, the first conductive layer 31, with the metal-doped graphene, an increase in specific resistance may be suppressed or minimized even when a thickness of the gate electrode 40 is reduced. Accordingly, the semiconductor device 100 may be further reduced in size. In addition, a degree of integration of the electronic device, e.g., a memory device, including the semiconductor device 100 may be further increased.

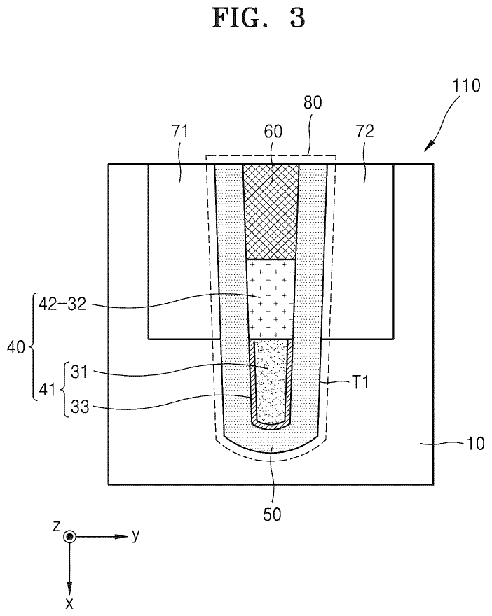

FIG. 3 is a cross-sectional view of a semiconductor device according to another embodiment.

A semiconductor device 110 of FIG. 3 may be substantially the same as the semiconductor device 100 of FIG. 1B, except that the lower filling portion 41 may include a barrier layer 33. When describing FIG. 3, any redundant description with the description of FIGS. 1A and 1B is not provided herein.

Referring to FIG. 3, the semiconductor device 110 may include the substrate 10 including the trench T1, the source region 71 and the drain region 72, arranged to be spaced apart from each other on the substrate 10, the gate insulating layer 50 covering the bottom surface and the inner surface of the trench T1, the gate electrode 40 including the lower filling portion 41 and the upper filling portion 42, the lower filling portion 41 being arranged in the trench T1 to be surrounded by the gate insulating layer 50 and filling the lower region of the trench T1, and the upper filling portion 42 being arranged on the lower filling portion 41 to be surrounded by the gate insulating layer 50 and filling the upper region of the trench T1, and the capping layer 60 arranged on the gate electrode 40.

The lower filling portion 41 may further include the barrier layer 33. The barrier layer 33 may be arranged in the trench T1 to cover the bottom surface and the lower region of the inner surface of the gate insulating layer 50. The first conductive layer 31 may fill the lower region of the trench T1 and be surrounded by the barrier layer 33. For example, the first conductive layer 31 may partially fill the lower region of the inside of the trench T1, and the barrier layer 33 may be provided between the gate insulating layer 50 and the first conductive layer 31 and surround the first conductive layer 31. Accordingly, the first conductive layer 31 may not be in direct contact with the bottom surface and the inner surface of the gate insulating layer 50. The barrier layer 33 may limit and/or prevent a material included in the first conductive layer 31 from being diffused to the gate insulating layer 50. The barrier layer 33 may include titanium nitride. For example, the barrier layer 33 may include TiN.

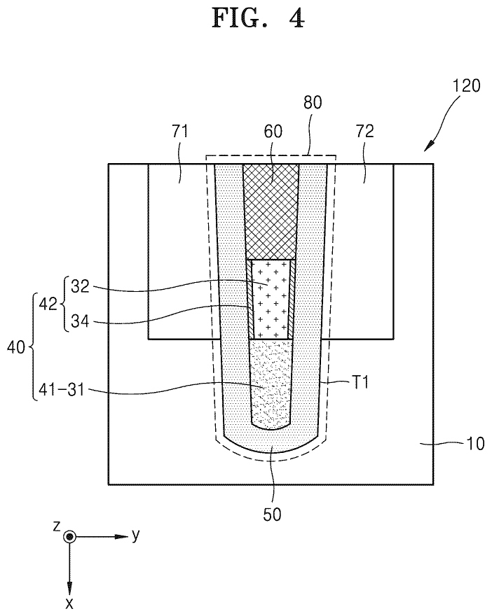

FIG. 4 is a cross-sectional view of a semiconductor device according to another embodiment.

A semiconductor device 120 of FIG. 4 may be substantially the same as the semiconductor device 100 of FIG. 1B, except that the upper filling portion 42 may include a two-dimensional material layer 34. When describing FIG. 4, any redundant description with the description of FIGS. 1A and 1B is not provided herein.

Referring to FIG. 4, the semiconductor device 120 may include the substrate 10 including the trench T1, the source region 71 and the drain region 72, arranged to be spaced apart from each other on the substrate 10, the gate insulating layer 50 covering the bottom surface and the inner surface of the trench T1, the gate electrode 40 including the lower filling portion 41 and the upper filling portion 42, the lower filling portion 41 being arranged in the trench T1 to be surrounded by the gate insulating layer 50 and filling the lower region of the trench T1, and the upper filling portion 42 being arranged on the lower filling portion 41 to be surrounded by the gate insulating layer 50 and filling the upper region of the trench T1, and the capping layer 60 arranged on the gate electrode 40.

The upper filling portion 42 may further include the two-dimensional material layer 34. The two-dimensional material layer 34 may be arranged in the trench T1 to be in contact with an upper region of a sidewall of the gate insulating layer 50. The two-dimensional material layer 34 may be arranged between the gate insulating layer 50 and the second conductive layer 32, and an inner surface of the two-dimensional material layer 34 may be in contact with the second conductive layer 32. Accordingly, the second conductive layer 32 may not be in direct contact with the gate insulating layer 50. The two-dimensional material layer 34 may surround the second conductive layer 32 and may not cover an upper surface and a lower surface of the second conductive layer 32. Accordingly, the upper surface and the lower surface of the second conductive layer 32 may not be in contact with the two-dimensional material layer 34. The lower surface of the second conductive layer 32 may be in direct contact with an upper surface of the first conductive layer 31. The two-dimensional material layer 34 may be arranged between the gate insulating layer 50 and the second conductive layer 32 and control a threshold voltage of the semiconductor device 120.

The two-dimensional material layer 34 may include various types of two-dimensional materials. For example, the two-dimensional material layer 34 may include at least one of black phosphorus, amorphous boron nitride, two-dimensional hexagonal boron nitride (h-BN), transition metal dichalcogenide, phosphorene, titanium oxide (TiOₓ), niobium oxide (NbOₓ), manganese oxide (MnOₓ), vanadium oxide (VOₓ), manganese trioxide (MnO₃), tantalum trioxide (TaO₃), tungsten trioxide (WO₃), molybdenum dichloride (MoCl₂), chromium trichloride (CrCl₃), ruthenium trichloride (RuCl₃), bismuth triiodide (BiI₃), lead tetrachloride (PbCl₄), germanium sulfide (GeS), gallium sulfide (GaS), germanium selenide (GeSe), gallium selenide (GaSe), platinum diselenide (PtSe₂), diindium triselenide(In₂Se₃), gallium telluride (GaTe), indium sulfide (InS), indium selenide (InSe), and indium telluride (InTe).

The transition metal dichalcogenide may include one metal element selected from among Mo, W, niobium (Nb), vanadium (V), Ta, Ti, zirconium (Zr), hafnium (Hf), technetium (Tc), rhenium (Re), copper (Cu), gallium (Ga), indium (In), tin (Sn), germanium (Ge), and lead (Pb), and one chalcogen element selected from among sulfur (S), selenium (Se), and tellurium (Te).

The two-dimensional h-BN has a high bandgap of about 6 eV and thus may function as an excellent charge blocking layer. Also, the two-dimensional h-BN may limit and/or prevent movement of metal atoms and thus may function as an excellent diffusion barrier. The two-dimensional material layer 34 may have a thickness of, e.g., about 0.3 nm to about 5 nm.

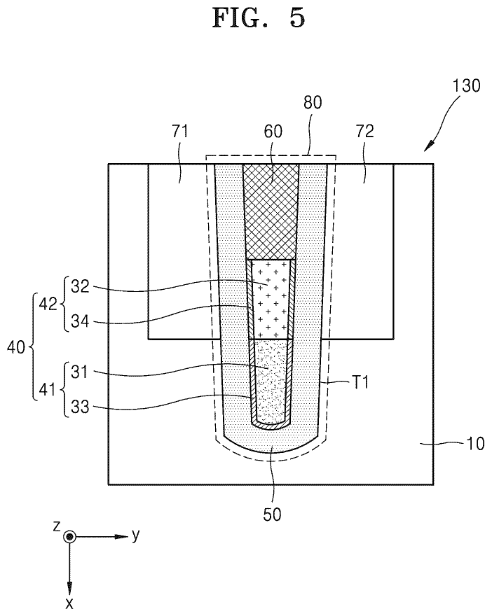

FIG. 5 is a cross-sectional view of a semiconductor device according to another embodiment.

A semiconductor device 130 of FIG. 5 may be substantially the same as the semiconductor device 100 of FIG. 1B, except that the lower filling portion 41 may include the barrier layer 33 and the upper filling portion 42 may include the two-dimensional material layer 34. The barrier layer 33 may be substantially the same as the barrier layer 33 of FIG. 3, and a two-dimensional material layer 34 may be substantially the same as the two-dimensional material layer 34 of FIG. 4. When describing FIG. 5, any redundant description with the description of FIGS. 1A to 4 is not provided herein.

Referring to FIG. 5, the semiconductor device 130 may include the substrate 10 including the trench T1, the source region 71 and the drain region 72, arranged to be spaced apart from each other on the substrate 10, the gate insulating layer 50 covering the bottom surface and the inner surface of the trench T1, the gate electrode 40 including the lower filling portion 41 and the upper filling portion 42, the lower filling portion 41 being arranged in the trench T1 to be surrounded by the gate insulating layer 50 and filling the lower region of the trench T1, and the upper filling portion 42 being arranged on the lower filling portion 41 to be surrounded by the gate insulating layer 50 and filling the upper region of the trench T1, and the capping layer 60 arranged on the gate electrode 40, the lower filling portion 41 may further include the barrier layer 33, and the upper filling portion 42 may further include the two-dimensional material layer 34.

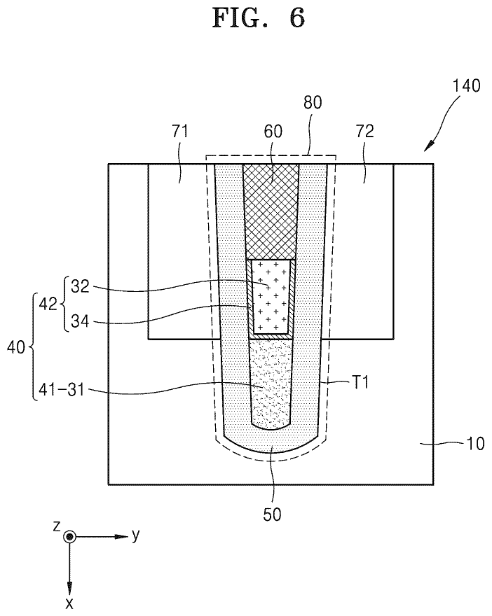

FIG. 6 is a cross-sectional view of a semiconductor device according to another embodiment.

A semiconductor device 140 of FIG. 6 may be substantially the same as the semiconductor device 120 of FIG. 4, except that the first conductive layer 31 and the second conductive layer 32 may be spaced apart from each other by the two-dimensional material layer 34. When describing FIG. 6, any redundant description with the description of FIGS. 1A to 4 is not provided herein.

Referring to FIG. 6, the semiconductor device 140 may include the substrate 10 including the trench T1, the source region 71 and the drain region 72, arranged to be spaced apart from each other by the trench T1, on the substrate 10, the gate insulating layer 50 covering the bottom surface and the inner surface of the trench T1, the gate electrode 40 including the lower filling portion 41 and the upper filling portion 42, the lower filling portion 41 being arranged in the trench T1 to be surrounded by the gate insulating layer 50 and filling the lower region of the trench T1, and the upper filling portion 42 being arranged on the lower filling portion 41 to be surrounded by the gate insulating layer 50 and filling the upper region of the trench T1, and the capping layer 60 arranged on the gate electrode 40, and the upper filling portion 42 may further include the two-dimensional material layer 34.

The two-dimensional material layer 34 may be arranged in the trench T1 to be in contact with the upper surface of the first conductive layer 31 and an upper region of the inner surface of the gate insulating layer 50. The two-dimensional material layer 34 may cover the upper surface of the first conductive layer 31 and the upper region of the inner surface of the gate insulating layer 50. The two-dimensional material layer 34 may surround the second conductive layer 32 and also cover the lower surface of the second conductive layer 32. The first conductive layer 31 and the second conductive layer 32 may be spaced apart from each other by the two-dimensional material layer 34. The lower surface of the second conductive layer 32 surrounded by the two-dimensional material layer 34 may not be in direct contact with the upper surface of the first conductive layer 31. The two-dimensional material layer 34 may be arranged between the first conductive layer 31 and the second conductive layer 32 and function as a barrier blocking contact between the first conductive layer 31 and the second conductive layer 32.

The second conductive layer 32 may be arranged to be surrounded by the two-dimensional material layer 34 and the capping layer 60. The second conductive layer 32 may include metal-doped graphene. The second conductive layer 32 may include the same metal-doped graphene as the first conductive layer 31 of FIG. 1B. A work function of graphene constituting the second conductive layer 32 may be controlled through metal doping.

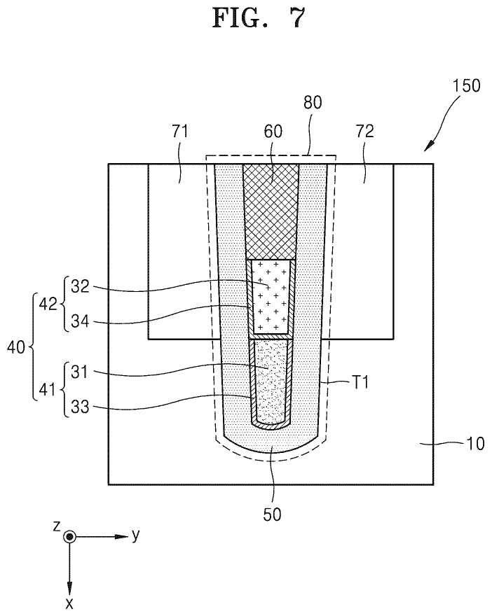

FIG. 7 is a cross-sectional view of a semiconductor device according to another embodiment.

A semiconductor device 150 of FIG. 7 may be substantially the same as the semiconductor device 130 of FIG. 5, except that the first conductive layer 31 and the second conductive layer 32 may be spaced apart from each other by the two-dimensional material layer 34. When describing FIG. 7, any redundant description with the description of FIGS. 1A to 5 is not provided herein.

Referring to FIG. 7, the semiconductor device 150 may include the substrate 10 including the trench T1, the source region 71 and the drain region 72, arranged to be spaced apart from each other by the trench T1, on the substrate 10, the gate insulating layer 50 covering the bottom surface and the inner surface of the trench T1, the gate electrode 40 including the lower filling portion 41 and the upper filling portion 42, the lower filling portion 41 being arranged in the trench T1 to be surrounded by the gate insulating layer 50 and filling the lower region of the trench T1, and the upper filling portion 42 being arranged on the lower filling portion 41 to be surrounded by the gate insulating layer 50 and filling the upper region of the trench T1, and the capping layer 60 arranged on the gate electrode 40, the lower filling portion 41 may further include the barrier layer 33, and the upper filling portion 42 may further include the two-dimensional material layer 34.

The two-dimensional material layer 34 may be arranged in the trench T1 to be in contact with the upper surface of the first conductive layer 31 and the upper region of the inner surface of the gate insulating layer 50. The two-dimensional material layer 34 may cover the upper surface of the first conductive layer 31 and the upper region of the inner surface of the gate insulating layer 50. The two-dimensional material layer 34 may surround the second conductive layer 32 and also cover the lower surface of the second conductive layer 32. The first conductive layer 31 and the second conductive layer 32 may be spaced apart from each other by the two-dimensional material layer 34. The lower surface of the second conductive layer 32 surrounded by the two-dimensional material layer 34 may not be in direct contact with the upper surface of the first conductive layer 31. The two-dimensional material layer 34 may be arranged between the first conductive layer 31 and the second conductive layer 32 and function as a barrier blocking contact between the first conductive layer 31 and the second conductive layer 32.

The second conductive layer 32 may be arranged to be surrounded by the two-dimensional material layer 34 and the capping layer 60. The second conductive layer 32 may include metal-doped graphene. The second conductive layer 32 may include the same metal-doped graphene as the first conductive layer 31 of FIG. 1B. The work function of the graphene constituting the second conductive layer 32 may be controlled through metal doping.

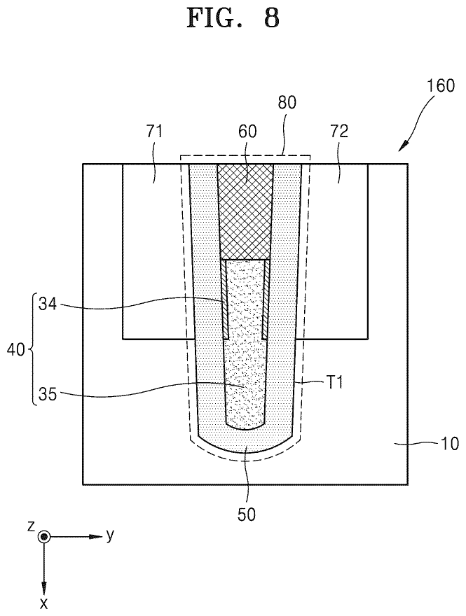

FIG. 8 is a cross-sectional view of a semiconductor device according to another embodiment.

A semiconductor device 160 of FIG. 8 may be substantially the same as the semiconductor device 120 of FIG. 4, except that a single conductive layer 35 is included, unlike the semiconductor device 120 of FIG. 4 including the first conductive layer 31 and the second conductive layer 32. When describing FIG. 8, any redundant description with the description of FIGS. 1A, 1B, and 4 is not provided herein.

Referring to FIG. 8, the semiconductor device 160 may include the substrate 10 including the source region 71 and the drain region 72 which are spaced apart from each other by the trench T1, the gate insulating layer 50 covering the bottom surface and the inner surface of the trench T1, the gate electrode 40 including the two-dimensional material layer 34 and the conductive layer 35, the two-dimensional material layer 34 covering the upper region of the sidewall of the gate insulating layer 50 in the trench T1, and the conductive layer 35 filling the trench T1 and arranged to be surrounded by the gate insulating layer 50 and the two-dimensional material layer 34, and the capping layer 60 on the gate electrode 40. A lower region of the conductive layer 35 may be surrounded by the gate insulating layer 50, and an upper region of the conductive layer 35 may be surrounded by the two-dimensional material layer 34.

The conductive layer 35 may include metal-doped graphene. The conductive layer 35 may include the same metal-doped graphene as the first conductive layer 31 of FIG. 1B. A work function of graphene constituting the conductive layer 35 may be controlled through metal doping.

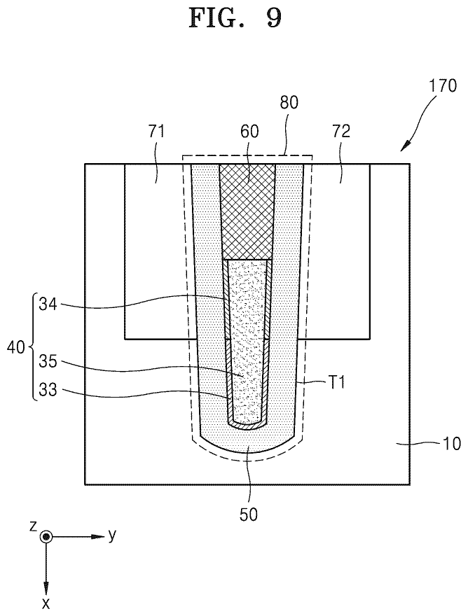

FIG. 9 is a cross-sectional view of a semiconductor device according to another embodiment.

A semiconductor device 170 of FIG. 9 may be substantially the same as the semiconductor device 130 of FIG. 5, except that a single conductive layer 35 is included, unlike the semiconductor device 130 of FIG. 5 including the first conductive layer 31 and the second conductive layer 32. When describing FIG. 9, any redundant description with the description of FIGS. 1A to 5 is not provided herein.

Referring to FIG. 9, the semiconductor device 170 may include the substrate 10 including the source region 71 and the drain region 72 which are spaced apart from each other by the trench T1, the gate insulating layer 50 covering the bottom surface and the inner surface of the trench T1, the gate electrode 40 including the two-dimensional material layer 34 and the conductive layer 35, the two-dimensional material layer 34 covering the upper region of the sidewall of the gate insulating layer 50 in the trench T1, and the conductive layer 35 filling the trench T1 and arranged to be surrounded by the gate insulating layer 50 and the two-dimensional material layer 34, and the capping layer 60 on the gate electrode 40. The lower region of the conductive layer 35 may be surrounded by the gate insulating layer 50, and the upper region of the conductive layer 35 may be surrounded by the two-dimensional material layer 34.

The conductive layer 35 may include metal-doped graphene. The conductive layer 35 may include the same metal-doped graphene as the first conductive layer 31 of FIG. 1B. The work function of the graphene constituting the conductive layer 35 may be controlled through metal doping.

The gate electrode 40 may further include the barrier layer 33 covering the bottom surface of the gate insulating layer 50 and the lower region of the inner surface of the gate insulating layer 50 in the trench T1. The lower region of the conductive layer 35 may be surrounded by the barrier layer 33. The barrier layer 33 may be the same as the barrier layer 33 described with reference to FIG. 3.

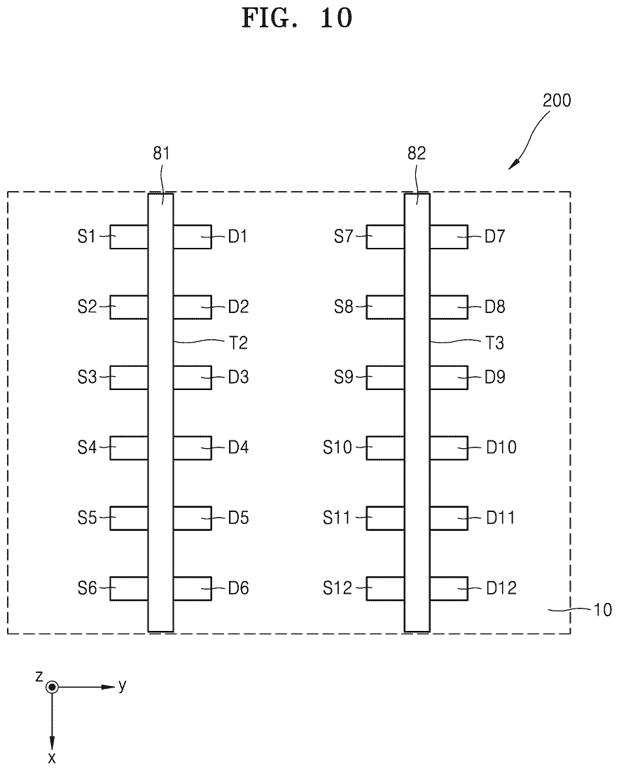

FIG. 10 is a diagram illustrating a configuration of a semiconductor device array according to an embodiment.

Referring to FIG. 10, a semiconductor device array 200 may include the substrate 10 including a plurality of trenches T2 and T3, a plurality of gate structures 81 and 82 respectively provided in the plurality of trenches T2 and T3, a plurality of source regions S1 to S12 and a plurality of drain regions D1 to D12 respectively spaced apart from each other with the plurality of trenches T2 and T3 arranged therebetween.

The plurality of trenches T2 and T3 may be spaced apart from each other in a second direction (y-direction) in the substrate 10, and extend parallel with each other in a first direction (x-direction) intersecting with the second direction (y-direction). In this case, the first direction (x-direction) may be perpendicular to the second direction (y-direction). Similar to the plurality of trenches T2 and T3, the plurality of gate structures 81 and 82 may be spaced apart from each other in the second direction (y-direction) and extend parallel with each other in the first direction (x-direction) intersecting with the second direction (y-direction).

The plurality of source region S1 to S6 may respectively face the plurality of drain region D1 to D6, with the first gate structure 81 therebetween. In addition, the plurality of source regions S7 to S12 may respectively face the plurality of drain regions D7 to D12, with the second gate structure 82 therebetween. One source region and one drain region facing each other among the plurality of source regions S1 to S6 and the plurality of drain regions D1 to D6 may constitute one semiconductor device together with the first gate structure 81 therebetween. Similarly, one source region and one drain region facing each other among the plurality of source regions S7 to S12 and the plurality of drain regions D7 to D12 may constitute one semiconductor device together with the second gate structure 82 therebetween. The semiconductor device may include any one of the semiconductor devices 100, 110, 120, 130, 140, 150, 160, and 170 described with reference to FIGS. 1A to 9. As described above, a plurality of semiconductor devices may be formed along each of the plurality of gate structures 81 and 82.

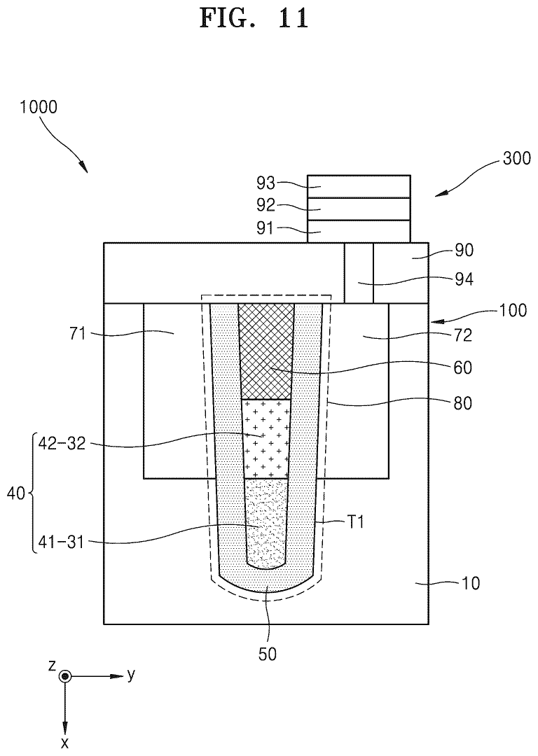

FIG. 11 is a cross-sectional view of a memory device according to an embodiment.

Referring to FIG. 11, a memory device 1000 may include the semiconductor device 100 and a capacitor 300. Although FIG. 11 illustrates that the memory device 1000 includes the semiconductor device 100 shown in FIG. 1B, the memory device 1000 may include any one of the semiconductor devices 110, 120, 130, 140, 150, 160, and 170 shown in FIGS. 3 to 9.

The memory device 1000 may include the source region 71 and the drain region 72 on the substrate 10 of the semiconductor device 100 and further include an interlayer insulating layer 90 covering the gate structure 80. The interlayer insulating layer 90 may include an insulating material.

The capacitor 300 may be arranged on the interlayer insulating layer 90. The capacitor 300 may include a lower electrode 91 arranged on the interlayer insulating layer 90, a dielectric layer 92 arranged on the lower electrode 91, and an upper electrode 93 arranged on the dielectric layer 92. The capacitor 300 may have a cylindrical shape, but is not limited thereto. In some embodiments, the capacitor 300 may also have a pillar shape.

The lower electrode 91 and the upper electrode 93 may include various types of conductive materials. The lower electrode 91 and the upper electrode 93 may include, e.g., at least one of polycrystal silicon, TiN, W, Ti, Ru, and tungsten nitride (WN). The dielectric layer 92 may include various types of insulating materials. The dielectric layer 92 may include, e.g., at least one high-k material from zirconium oxide (ZrO₂), aluminum oxide (Al₂O₃), and hafnium oxide (Hf₂O₃).

A via hole may be formed in a partial region of the interlayer insulating layer 90. The memory device 1000 may further include a contact 94 filled in the via hole. For example, the via hole may be formed to expose the drain region 72, and the contact 94 may be formed in contact with the drain region 72. The capacitor 300 may be formed on the interlayer insulating layer 90 to be in contact with the contact 94. Accordingly, the capacitor 300 may be electrically connected to the drain region 72 through the contact 94. The shape and structure of the contact 94 may be changed, and the contact 94 may include various types of conductive materials.

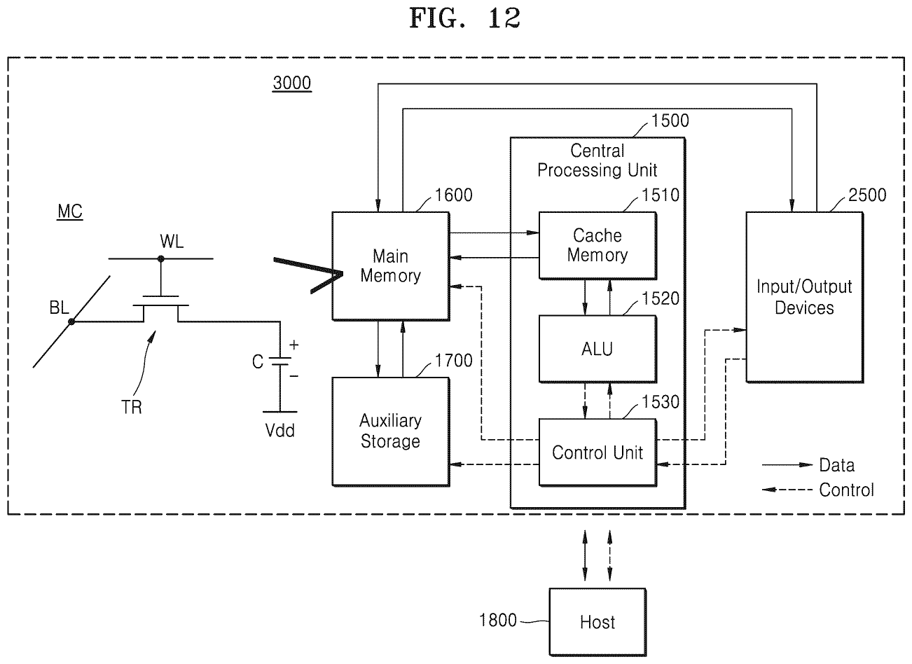

FIG. 12 is a conceptual diagram schematically illustrating a device architecture that can be applied to an electronic apparatus according to an example embodiment.

Referring to FIG. 12, an electronic device architecture 3000 may include a memory 1510 and a control unit 1530, and may further include an arithmetic logic unit (ALU) 1520. The memory 1510 may be a cache memory. The memory 1510, the ALU 1520, and the control unit 1530 may be electrically connected to one another in a central processing unit (CPU) 1500. For example, the electronic device architecture 3000 may be implemented as one chip including the memory 1510, the ALU 1520, and the control unit 1530. For example, the memory 1510, the ALU 1520, and the control unit 1530 may be connected to each other by a metal line in an on-chip and directly communicate with each other. The memory 1510, the ALU 1520, and the control unit 1050 may be integrated monolithically on one substrate to constitute one chip. Apart from the CPU 1500, a main memory 1600, an auxiliary storage 1700 may be provided, and an input/output devices 2500 may be provided. The electronic device architecture (chip) 3000 may be an on-chip memory processing unit. The CPU 1500 may control the main memory 1600 to read data from and/or write data to the memory 1600 in response to a request from an external host 1800. The CPU 1500 may be configured to exchange data with the external host 1800. The main memory 1600, the cache memory 1510, the ALU 1520, and/or the control unit 1530 may each independently include one or more of the semiconductor devices 100, 110, 120, 130, 140, 150, 160, or 170, semiconductor device array 200, or memory device 1000 described above.

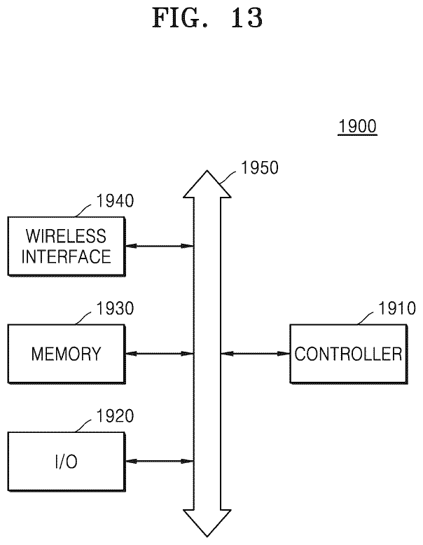

FIG. 13 is a block diagram of an electronic apparatus according to an embodiment.

The electronic apparatus 1900 may constitute a wireless communication device or a device capable of transmitting and/or receiving information in a wireless environment. The electronic apparatus 1900 may include a controller 1910, an input/output device (I/O) 1920, a memory 1930, and a wireless interface 1940, and these components may be interconnected to each other through a bus 1950.

The controller 1910 may include at least one of a microprocessor, a digital signal processor, or a processing device similar thereto. The input/output device 1920 may include at least one of a keypad, a keyboard, and a display. The memory 1930 may be used to store instructions executed by controller 1910. For example, the memory 1930 may be used to store user data. The electronic apparatus 1900 may use the wireless interface 1940 to transmit/receive data through a wireless communication network. The wireless interface 1940 may include an antenna and/or a wireless transceiver. In some embodiments, the electronic system 4200 may be used in a communication interface protocol of a variety of communication systems, for example, code division multiple access (CDMA), global system for mobile communications (GSM), north American digital cellular (NADC), extended-time division multiple access (E-TDMA), and/or wide band code division multiple access (WCDMA). The electronic apparatus 1900 may include one or more of the include one or more of the semiconductor devices 100, 110, 120, 130, 140, 150, 160, or 170, semiconductor device array 200, or memory device 1000 described above.

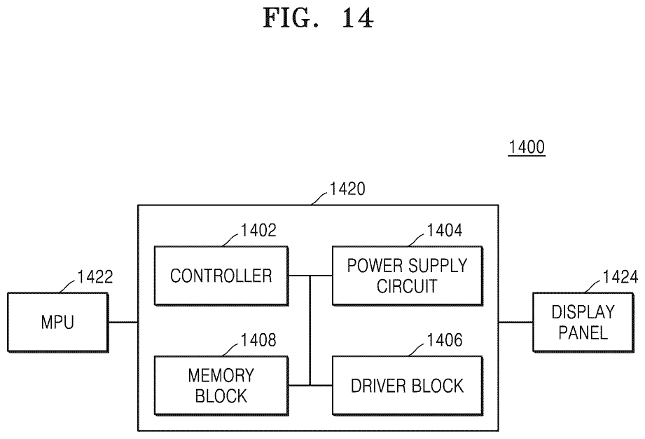

FIG. 14 of a display apparatus according to an embodiment.

Referring to FIG. 14, the display apparatus 1400 may include a display driver IC (DDI) 1420 including a controller 1402, a power supply circuit 1404, a driver block 1406, and a memory block 1408. The controller 1402 receives and decodes a command applied from a main processing unit (MPU) 1422, and controls each block of the DDI 1420 to implement an operation according to the command. The power supply circuit unit 1404 generates a driving voltage in response to the control of the control unit 1402. The driver block 1406 drives a display panel 1424 using the driving voltage generated by the power supply circuit unit 1404 in response to the control of the controller 1402. The display panel 1424 may be a liquid crystal display panel or a plasma display panel. The memory block 1408 is a block for temporarily storing commands input to the controller 1402 or control signals output from the controller 1402, or for storing necessary data, and may include a memory, such as RAM or ROM. The power supply circuit unit 1404 and the driver block 1406 may include the electronic device according to the embodiment described above. The display apparatus 1400 may include one or more of the semiconductor devices 100, 110, 120, 130, 140, 150, 160, 170, or 180 described above in the controller 1402, memory block 1408, driver block 1406, MPU 1422, or other portions.

Based on the aforementioned descriptions, according to the embodiments of technical ideas of the disclosure, a memory device including a having a fast driving speed, low power consumption, and improved memory capacity may be provided. The memory device may include a phase change material.

According to the embodiments of the disclosure, the semiconductor device may include a conductive layer including metal-doped graphene having a controllable work function, and the semiconductor device may control a threshold voltage.

In addition, by forming a gate electrode with metal-doped graphene, an increase in specific resistance due to a decrease in thickness of the gate electrode may be suppressed.

While the electronic device described above have been described with reference to the embodiments described in the drawings, such descriptions are merely an example, and it will be understood by those of ordinary skill in the art that various modifications and other equivalent embodiments can be made therefrom. Therefore, the disclosed embodiments should be considered in a descriptive sense rather than a restrictive sense. The scope of rights is not limited to description above, but rather is set forth in the claims, and all the differences in a range equivalent thereto should be interpreted as being included in the scope of rights.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate including a trench, a source region, and a drain region, the source region and the drain region spaced apart from each other by the trench;
a gate insulating layer covering a bottom surface of the trench and an inner surface of the trench; and
a gate electrode in the trench,
the gate electrode including a lower filling portion and an upper filling portion surrounded by the gate insulating layer, the lower filling portion in the trench and filling a lower region of the trench, and the upper filling portion on the lower filling portion and filling an upper region of the trench, wherein
the lower filling portion includes a first conductive layer surrounded by the gate insulating layer and filling the lower region of the trench,
the upper filling portion includes a second conductive layer surrounded by the gate insulating layer and filling the upper region of the trench, and
the first conductive layer includes graphene doped with metal.

2. The semiconductor device of claim 1, wherein the graphene doped with metal comprises at least one of ruthenium (Ru), aluminum (Al), titanium (Ti), platinum (Pt), tantalum (Ta), rhodium (Rh), iridium (Ir), cobalt (Co), and tungsten (W).

3. The semiconductor device of claim 1, wherein a ratio of metal to carbon in the graphene doped with metal is 0.2 at % to 50 at %.

4. The semiconductor device of claim 1, wherein, in the graphene doped with metal, a ratio of carbon having an sp² bond structure to total carbon is 50% to 99%,
wherein the graphene doped with metal comprises nanocrystalline graphene, and
the nanocrystalline graphene comprises crystals each having a size of 0.5 nm to 100 nm.

5. The semiconductor device of claim 1, wherein the second conductive layer comprises at least one of polysilicon, Al, copper (Cu), Ru, Rh, Ir, molybdenum (Mo), W, palladium (Pd), Pt, Co, Ta, Ti, nickel (Ni), titanium nitride (TiN), and tantalum nitride (TaN).

6. The semiconductor device of claim 1, further comprising:
a capping layer on the gate electrode.

7. The semiconductor device of claim 1, wherein
the lower filling portion further comprises a barrier layer covering a bottom surface of the gate insulating layer and a lower region of an inner surface of the gate insulating layer, and
the barrier layer surrounds the first conductive layer in the trench.

8. The semiconductor device of claim 1, wherein
the upper filling portion further comprises a two-dimensional material layer in contact with an upper region of the inner surface of the gate insulating layer, and
the two-dimensional material layer surrounds the second conductive layer.

9. The semiconductor device of claim 8, wherein the two-dimensional material layer comprises at least one of black phosphorus, amorphous boron nitride, two-dimensional hexagonal boron nitride (h-BN), phosphorene, a transition metal dichalcogenide, titanium oxide (TiOₓ), niobium oxide (NbOₓ), manganese oxide (MnOₓ), vanadium oxide (VOₓ), manganese trioxide (MnO₃), tantalum trioxide (TaO₃), tungsten trioxide (WO₃), molybdenum dichloride (MoCl₂), chromium trichloride (CrCl₃), ruthenium trichloride (RuCl₃), bismuth triiodide (BiI₃), lead tetrachloride (PbCl₄), germanium sulfide (GeS), gallium sulfide (GaS), germanium selenide (GeSe), gallium selenide (GaSe), platinum diselenide (PtSe₂), diindium triselenide(In₂Se₃), gallium telluride (GaTe), indium sulfide (InS), indium selenide (InSe), and indium telluride (InTe).

10. The semiconductor device of claim 9, wherein
the transition metal dichalcogenide comprises a metal element and a chalcogen element,
the metal element includes one of Mo, W, niobium (Nb), vanadium (V), Ta, Ti, zirconium (Zr), hafnium (Hf), technetium (Tc), rhenium (Re), Cu, gallium (Ga), indium (In), tin (Sn), germanium (Ge), and lead (Pb), and
the chalcogen element includes one of sulfur (S), selenium (Se), and tellurium (Te).

11. The semiconductor device of claim 8, wherein the two-dimensional material layer covers an upper surface of the first conductive layer.

12. The semiconductor device of claim 8, wherein the two-dimensional material layer has a thickness of 0.3 nm to 5 nm.

13. A semiconductor device comprising:
a substrate including a trench, a source region, and a drain region, the source region and the drain region being spaced apart from each other by the trench;
a gate insulating layer covering a bottom surface of the trench and an inner surface of the trench; and
a gate electrode in the trench,
the gate electrode including a two-dimensional material layer and a conductive layer, the two-dimensional material layer covering an upper region of a sidewall of the gate insulating layer in the trench, and the conductive layer filling the trench and being surrounded by the gate insulating layer and the two-dimensional material layer,
wherein the conductive layer includes graphene doped with metal.

14. The semiconductor device of claim 13, wherein the graphene doped with metal comprises at least one of ruthenium (Ru), aluminum (Al), titanium (Ti), platinum (Pt), tantalum (Ta), rhodium (Rh), iridium (Ir), cobalt (Co), and tungsten (W).

15. The semiconductor device of claim 13, wherein, in the graphene doped with metal, a ratio of metal to carbon is 0.2 at % to 50 at %.

16. The semiconductor device of claim 13, wherein, in the graphene doped with metal, a ratio of carbon having an sp² bond structure to total carbon is 50% to 99%,
wherein the graphene doped with metal comprises nanocrystalline graphene, and
the nanocrystalline graphene comprises crystals each having a size of 0.5 nm to 100 nm.

17. The semiconductor device of claim 13, further comprising:
a capping layer on the gate electrode.

18. The semiconductor device of claim 13, wherein
the gate electrode further comprises a barrier layer,
the barrier layer covers a bottom surface of the gate insulating layer and a lower region of an inner surface of the gate insulating layer in the trench.

19. The semiconductor device of claim 13, wherein the two-dimensional material layer comprises at least one of black phosphorus, amorphous boron nitride, two-dimensional hexagonal boron nitride (h-BN), phosphorene, a transition metal dichalcogenide, titanium oxide (TiOₓ), niobium oxide (NbOₓ), manganese oxide (MnOₓ), vanadium oxide (VOₓ), manganese trioxide (MnO₃), tantalum trioxide (TaO₃), tungsten trioxide (WO₃), molybdenum dichloride (MoCl₂), chromium trichloride (CrCl₃), ruthenium trichloride (RuCl₃), bismuth triiodide (BiI₃), lead tetrachloride (PbCl₄), germanium sulfide (GeS), gallium sulfide (GaS), germanium selenide (GeSe), gallium selenide (GaSe), platinum diselenide (PtSe₂), diindium triselenide(In₂Se₃), gallium telluride (GaTe), indium sulfide (InS), indium selenide (InSe), and indium telluride (InTe).

20. The semiconductor device of claim 19, wherein
the transition metal dichalcogenide comprises a metal element and a chalcogen element,
the metal element includes one of molybdenum (Mo), W, niobium (Nb), vanadium (V), Ta, Ti, zirconium (Zr), hafnium (Hf), technetium (Tc), rhenium (Re), copper (Cu), gallium (Ga), indium (In), tin (Sn), germanium (Ge), and lead (Pb), and
the chalcogen element includes one of sulfur (S), selenium (Se), and tellurium (Te).
